(19) United States
(12) Patent Application Publication
(10) Pub. No.: US 2017/0279247 A1
(43) Pub. Date: Sep. 28, 2017

(54) SEALED DEVICE AND METHODS FOR MAKING THE SAME

(71) Applicant: CORNING INCORPORATED, CORNING, NY (US)

(72) Inventors: Stephan Lvovich Logunov, Corning, NY (US); Mark Alejandro Quesada, Horseheads, NY (US); Alexander Mikhailovich Streltsov, Corning, NY (US)

(21) Appl. No.: 15/506,543

(22) PCT Filed: Aug. 21, 2015
(86) PCT No.: PCT/US15/46267

§ 371 Date: Feb. 24, 2017

Related U.S. Application Data
(60) Provisional application No. 62/041,329, filed on Aug. 25, 2014.
(60) Provisional application No. 62/207,447, filed on Aug. 20, 2015.

(51) Int. Cl. H01S 5/40; G02F 1/1335; H01S 5/022

(52) U.S. Cl. CPC H01S 5/4062; H01S 5/0222; G02F 1/133603; H01L 25/0753

(57) ABSTRACT

Disclosed herein are sealed devices comprising a first glass substrate; a second glass substrate; an optional sealing layer between the first and second glass substrates; and at least one seal between the first and second glass substrates. The sealed devices may comprise at least one cavity containing at least one component chosen from laser diodes, light emitting diodes, organic light emitting diodes, quantum dots, and combinations thereof. Also disclosed herein are display devices comprising such sealed devices and methods for making sealed devices.

This application claims the benefit of priority to U.S. Provisional Application Ser. No. 62/041,329 filed Aug. 25, 2014 and to U.S. Provisional Application Ser. No. 62/207,447 filed Aug. 20, 2015, the content of each being relied upon and incorporated herein by reference in their entirety.

### FIELD OF THE DISCLOSURE

The disclosure relates generally to sealed devices and display devices comprising such sealed devices, and more particularly to sealed glass devices comprising color-converting elements and methods for making the same.

### BACKGROUND

Sealed glass packages and casings are increasingly popular for application to electronics and other devices that may benefit from a hermetic environment for sustained operation. Exemplary devices which may benefit from hermetic packaging include displays, such as televisions, comprising light emitting diodes (LEDs), organic light emitting diodes (OLEDs), and/or quantum dots (QDs). Other exemplary devices include, for instance, sensors, optical devices, 3D inkjet printers, solid-state lighting sources, and photovoltaic structures, to name a few.

Liquid crystal displays (LCDs) are commonly used in various electronics, such as cell phones, laptops, electronic tablets, televisions, and computer monitors. Conventional LCDs typically comprise a blue light emitting diode (LED) and a phosphor color converter, such as an yttrium aluminum garnet (YAG) phosphor. However, such LCDs can be limited, as compared to other display devices, in terms of brightness, contrast ratio, efficiency, and/or viewing angle. For instance, to compete with organic light emitting diode (OLED) technology, there is a demand for higher contrast ratio, color gamut, and brightness in conventional LCDs while also balancing product cost and power requirements, e.g., in the case of handheld devices.

Quantum dots have emerged as an alternative to phosphors and can, in some instances, provide improved precision and/or narrower emission lines, which can improve, e.g., the LCD color gamut. LCD displays utilizing quantum dots as color converters can comprise, for example, a glass tube or capillary containing quantum dots, which can be placed between the LED and the light guide. Such tubes can be sealed on both ends and can be filled with quantum dots, such as green and red emitting quantum dots. However, such devices can, for example, result in significant material waste and/or can be complex to produce.

For example, the process for making sealed devices can be challenging due to harsh processing conditions. Glass, ceramic, and/or glass-ceramic substrates can be sealed by placing the substrates in a furnace, with or without an epoxy or other sealing material. However, the furnace typically operates at high processing temperatures which are unsuitable for many devices, such as OLEDs and QDs. Glass substrates can also be sealed using glass frit, e.g., by placing glass frit between the substrates and heating the frit with a laser or other heat source to seal the package. However, glass frit may require higher processing temperatures unsuitable for devices such as OLEDs and/or may produce undesirable gases upon sealing. Frit seals may also have undesirably low tensile strength and shear strain.

The process for making sealed devices can also be challenging due to manufacturing constraints. For example, sealing defects can occur during manufacture which can compromise the hermeticity of the sealed package. In the case of laser frit sealing, exposing the frit material to a laser twice in the same area may result in sealing defects, making it difficult to form a continuous seal. Special frit sealing recipes and/or techniques may thus be necessary to obtain a fully sealed glass package, such as turning the laser power on and off to ensure no overlap between the start and stop point, or powering the laser up or down gradually in areas where overlap may occur.

However, individually sealing each glass package using such methods can be time-consuming, complex, and/or costly. Commercial manufacturing processes for making sealed devices often call for quick, high-speed sealing of multiple packages at one time, often on large substrates that are subsequently cut after sealing. For example, several objects to be sealed (e.g., from tens to hundreds to thousands of objects) may be placed on a large sheet of glass, covered by another glass sheet, and sealed, followed by cutting (or “singulating”) to create multiple individually sealed packages. High laser translation speeds and simple patterns, e.g., squares or rectangles formed by creating simple intersecting weld lines may be employed to maximize efficiency.

In such high-throughput operations, the separation or cutting lines often cross the laser weld seal lines and may damage or crack the seal. Sealing defects, particularly in the case of hermetic seals, can occur when glass packages are singulated or cut away from the larger sealed substrates. These cracks can propagate and compromise the permeability of the package to potential contaminants, such as air and water.

Accordingly, it would be advantageous to provide methods for laser sealing glass substrates, which may, among other advantages, decrease manufacturing cost and/or complexity, decrease sealing defects, increase seal strength and/or impermeability, increase production rate, and/or increase yield. It would also be advantageous to provide sealed devices for displays and other electronic devices which can reduce material waste, thereby lowering the cost of such devices, and/or which can simplify product assembly, thereby reducing production time. The resulting sealed packages can be used to protect a wide array of electronics and other components, such as light emitting structures or color converting elements, e.g., laser diodes (LDs), LEDs, OLEDs, and/or QDs.

### SUMMARY

The disclosure relates, in various embodiments, to sealed devices comprising a first glass substrate having a first surface, the first surface comprising an array of cavities, wherein at least one cavity in the array of cavities contains at least one color-converting element; a second glass substrate; and at least one seal between the first glass substrate and the second glass substrate, the seal extending around the at least one cavity containing the at least one color-converting element. Display devices comprising such sealed devices are also disclosed herein.

The disclosure also relates to sealed devices comprising a first glass substrate having a first surface, the first surface comprising an array of cavities, wherein at least one cavity in the array of cavities contains a color-converting element; a second glass substrate positioned on the first surface; an optional sealing layer positioned between the first and second glass substrates; and a first seal formed between the first glass substrate and the second glass substrate, the first seal extending around the least one cavity containing the at least one color-converting element and the first seal comprising a glass-to-glass seal or comprising a glass-to-sealing layer-to-glass seal.

According to various embodiments, a second surface of the second glass substrate can contact the first surface of the first glass substrate to form a seal between the first and second glass substrates. In other embodiments, the seal between the first and second glass substrates can be formed using a sealing layer disposed between the substrates. According to further embodiments, the color-converting elements may be chosen from quantum dots, fluorescent dyes, and/or red, green, and/or blue phosphors.

Also disclosed herein are sealed devices comprising a first glass substrate, a second glass substrate, a sealing layer positioned between the first and second glass substrates, and a laser weld seal formed between the first and the second glass substrates, wherein the laser weld seal comprises a hermetic seal reinforced by a non-hermetic seal. In various embodiments, the non-hermetic seal and the hermetic seal may substantially overlap. According to additional embodiments, the sealed devices may further comprise at least one cavity containing at least one component chosen from LDs, LEDs, OLEDs, and/or QDs.

Also disclosed herein are methods for making a sealed device, the methods comprising brining a first surface of a first glass substrate and a second surface of a second glass substrate into contact with a sealing layer to form a sealing interface, directing a first laser operating at a first predetermined wavelength onto the sealing interface to form a hermetic seal between the first and second glass substrates, and directing a second laser operating at a second predetermined wavelength onto the sealing interface to form a non-hermetic seal between the first and second glass substrates.

The disclosure further relates to methods for making a sealed device, the methods comprising placing at least one color-converting element in at least one cavity in an array of cavities on a first surface of a first glass substrate; bringing a second surface of a second glass substrate into contact with the first surface of the first glass substrate, optionally with a sealing layer between the first and second substrates, to form a sealing interface; and directing a laser beam operating at a predetermined wavelength onto the sealing interface to form a seal between the first substrate and the second substrate, the seal extending around the at least one cavity containing the at least one color-converting element.

Still further disclosed herein are methods for making a sealed device, the methods comprising bringing a first surface of a first glass substrate and a second surface of a second glass substrate into contact with a sealing layer to form a sealing interface, directing a laser operating at a predetermined wavelength onto the sealing interface to form at least one seal line between the first glass substrate and the second glass substrate, the at least one seal line defining at least two sealed regions; and separating the at least two sealed regions along at least one separation line, wherein the at least one seal line and the at least one separation line do not intersect.

Additional features and advantages of the disclosure will be set forth in the detailed description which follows, and in part will be readily apparent to those skilled in the art from that description or recognized by practicing the methods as described herein, including the detailed description which follows, the claims, as well as the appended drawings.

It is to be understood that both the foregoing general description and the following detailed description present various embodiments of the disclosure, and are intended to provide an overview or framework for understanding the nature and character of the claims. The accompanying drawings are included to provide a further understanding of the disclosure, and are incorporated into and constitute a part of this specification. The drawings illustrate various embodiments of the disclosure and together with the description serve to explain the principles and operations of the disclosure.

### BRIEF DESCRIPTION OF THE DRAWINGS

The following detailed description can be further understood when read in conjunction with the following drawings.

FIG. 1 illustrates optical components of an LCD device;

FIG. 2 illustrates optical components of an exemplary LCD device according to certain embodiments of the present disclosure;

FIG. 3 illustrates a cross-sectional view of a sealed device according to various embodiments of the disclosure;

FIG. 4 illustrates a top view of a sealed device according to further embodiments of the disclosure;

FIGS. 5A-C illustrate various laser welds for sealing an article according to certain embodiments of the disclosure;

FIG. 6A illustrates a top view of an article with a plurality of laser welds defining a plurality of sealed sections and a plurality of separation lines for singulating the sealed sections;

FIG. 6B illustrates a top view of a single sealed section of the article of FIG. 6A;

FIG. 6C illustrates a top view of a sealed device according to various embodiments of the disclosure;

FIG. 7 illustrates sealing defects created at the intersection of separation and laser weld lines;

FIG. 8 illustrates intersecting weld and separation lines without sealing defects;

FIG. 9A illustrates a top view of an article with a plurality of laser welds defining a plurality of sealed sections and a plurality of separation lines for singulating the sealed sections;

FIG. 9B illustrates a top view of a single sealed section of the article of FIG. 9A;

FIG. 9C illustrates a top view of four sealed sections of the article of FIG. 9A;

FIG. 10 illustrates separation lines for singulating four sealed sections of an article;

FIG. 11A illustrates a top view of an article with a plurality of laser welds defining a plurality of sealed sections and a plurality of separation lines for singulating the sealed sections;

FIG. 11B illustrates a top view of a single sealed section of the article of FIG. 11A;

FIG. 11C illustrates a top view of a sealed device according to various embodiments of the disclosure;

FIG. 12 illustrates a top view of a sealed device according to certain embodiments of the disclosure; and

FIGS. 13A-B illustrate top views of sealed devices according to further embodiments of the disclosure.

### DETAILED DESCRIPTION

Devices

Disclosed herein are sealed devices comprising a first glass substrate having a first surface, the first surface comprising an array of cavities, wherein at least one cavity in the array of cavities contains at least one color-converting element; a second glass substrate; and at least one seal between the first glass substrate and the second glass substrate, the seal extending around the at least one cavity containing the at least one color-converting element. Also disclosed herein are sealed devices comprising a first glass substrate having a first surface, the first surface comprising an array of cavities, wherein at least one cavity in the array of cavities contains a color-converting element; a second glass substrate positioned on the first surface; an optional sealing layer positioned between the first and second glass substrates; and a first seal formed between the first glass substrate and the second glass substrate, the first seal extending around the least one cavity containing the at least one color-converting element and the first seal comprising a glass-to-glass seal or comprising a glass-to-sealing layer-to-glass seal. Further disclosed herein are sealed devices comprising a first glass substrate, a second glass substrate, a sealing layer positioned between the first and second glass substrates, and a laser weld seal formed between the first and the second glass substrates, wherein the laser weld seal comprises a hermetic seal reinforced by a non-hermetic seal. Display devices comprising such sealed devices are also disclosed herein.

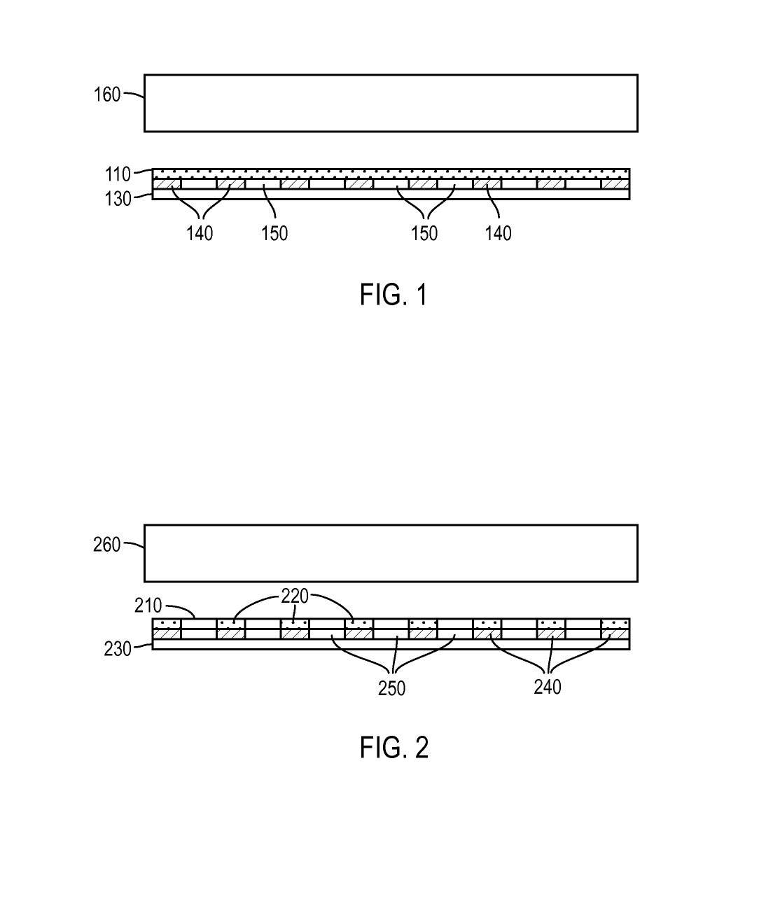

FIG. 1 depicts the optical components of an exemplary LCD device. With reference to FIG. 1, a sealed device 110 is illustrated, such as a capillary tube filled with quantum dots, positioned between an LED array 130 and a backlight unit 160. As demonstrated in FIG. 1, the LED array can comprise multiple, discrete LEDs 140. In such an arrangement, these quantum dots are presented adjacent to and over “dead” space 150, e.g., spaces where there is no LED present. This arrangement can, in various embodiments, result in significant material waste.

FIG. 2 depicts an exemplary backlit device, such as an LCD, according to various embodiments of the disclosure. A sealed device 210 is positioned between an LED array 230 and a backlight unit 260. As illustrated in FIG. 2, the sealed device 210 can comprise an array of cavities comprising color-converting elements 220, which can substantially align with the individual LEDs 240 in the LED array 230. According to various embodiments, some or all of the areas in the sealed device adjacent to the “dead” space 250 in the LED array can be free or substantially free of color-converting elements, thereby reducing material waste.

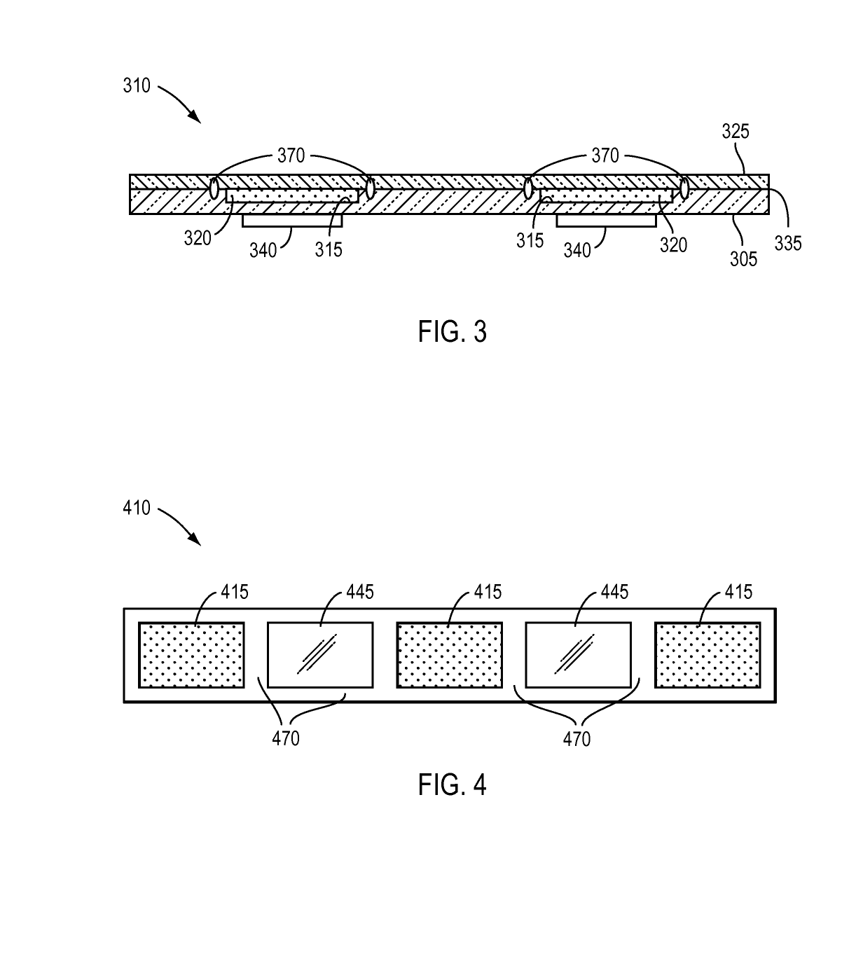

FIG. 3 is a cross-sectional view of a sealed device 310 according to certain embodiments of the disclosure. The device can comprise a first glass substrate 305, having a first surface (not labeled) comprising an array of cavities 315. The device can further comprise a second glass substrate 325, having a second surface (not labeled), which can contact the first surface of the first glass substrate 305, to form a sealing (or substrate) interface 335. At least one of the cavities 315 can comprise at least one color-converting element 320. At least one of the cavities 315 can be substantially aligned with, e.g., adjacent to, on top of, or below, at least one LED 340. The device can further comprise at least one seal 370 between the first and second surfaces, and the seal can extend, in certain embodiments, around at least one of the cavities 315, e.g., at least one of the cavities 315 comprising the at least one color-converting element 320.

Of course, in the cross-sectional view depicted in FIG. 3, only seal lines transverse to the viewing plane are visible, and such a depiction should not limit the scope of the claims appended herewith. FIG. 4 provides an elevated view of a portion of a sealed device 410, which illustrates an exemplary seal pattern, wherein at least one seal 470 extends around at least one of the cavities 415. The device 410 can comprise empty spaces 445 not comprising color-converting elements. These spaces 445 can be formed either by the absence of a cavity 415, or a cavity 415 that does not comprise a color-converting element. The seal 470 can extend around one or more cavities 415, such as two or more cavities, three or more cavities, and so on, or the seal can extend around all the cavities 415, individually or in groups. The seal 470 can, in some embodiments, separate some or all of the cavities 415 into discrete sealed pockets which can contain, e.g., at least one color-converting element. Exemplary sealing methods are described below in more detail.

As depicted in FIG. 4, the glass substrates can comprise at least one edge, for instance, at least two edges, at least three edges, or at least four edges, and the substrates can be sealed at the edges. By way of a non-limiting example, the first and/or second glass substrates may comprise a rectangular or square glass sheet having four edges, although other shapes and configurations are envisioned and are intended to fall within the scope of the disclosure. One or more seals 470 can therefore seal the edges of the device and/or extend around at least one of the cavities 415.

In additional embodiments, the at least one seal 370, 470 can comprise a combined or reinforced seal, as discussed in further detail with respect to FIG. 12. According to further embodiments, two glass substrates may be sealed together with a sealing layer disposed therebetween, wherein the seal comprises a combined or reinforced seal. For example, the at least one seal can comprise a combined hermetic and non-hermetic seal, which can, in some embodiments, substantially overlap. Without wishing to be bound by theory, it is believed that a relatively weaker hermetic seal can be strengthened by the addition of a non-hermetic seal, which may be coextensive with the hermetic seal. In additional embodiments, the non-hermetic seal may be adjacent the hermetic seal or proximate the hermetic seal.

It is to be understood that multiple seals can be used to weld together various parts of the glass substrates in any given pattern(s). While FIG. 4 depicts seals having a rectangular shape, it should be noted that the seal can have any shape and/or size, which can be uniform throughout the device or can differ along the length of the device. Furthermore, while FIGS. 3-4 depict sealed cavities 315, 415 each comprising a color-converting element, it is to be understood that various cavities can be empty or otherwise free of color-converting elements, these empty cavities thus being sealed or unsealed as appropriate or desired.

According to various embodiments, the seal or weld can have a width ranging from about 50 microns to about 1 mm, such as from about 70 microns to about 500 microns, from about 100 microns to about 300 microns, from about 120 microns to about 250 microns, from about 130 microns to about 200 microns, from about 140 microns to about 180 microns, or from about 150 microns to about 170 microns, including all ranges and subranges therebetween.

The first and second glass substrates may comprise any glass known in the art for use in a backlit display, such as an LCD, including, but not limited to, soda-lime silicate, aluminosilicate, alkali-aluminosilicate, borosilicate, alkali-borosilicate, aluminoborosilicate, alkali-aluminoborosilicate, and other suitable glasses. These substrates may, in various embodiments, be chemically strengthened and/or thermally tempered. Non-limiting examples of suitable commercially available substrates include EAGLE XG®, Lotus™, Willow®, and Gorilla® glasses from Corning Incorporated, to name a few. Glasses that have been chemically strengthened by ion exchange may be suitable as substrates according to some non-limiting embodiments.

During the ion exchange process, ions within a glass sheet at or near the surface of the glass sheet may be exchanged for larger metal ions, for example, from a salt bath. The incorporation of the larger ions into the glass can strengthen the sheet by creating a compressive stress in a near surface region. A corresponding tensile stress can be induced within a central region of the glass sheet to balance the compressive stress.

Ion exchange may be carried out, for example, by immersing the glass in a molten salt bath for a predetermined period of time. Exemplary salt baths include, but are not limited to, KNO₃, LiNO₃, NaNO₃, RbNO₃, and combinations thereof. The temperature of the molten salt bath and treatment time period can vary. It is within the ability of one skilled in the art to determine the time and temperature according to the desired application. By way of a non-limiting example, the temperature of the molten salt bath may range from about 400° C. to about 800° C., such as from about 400° C. to about 500° C., and the predetermined time period may range from about 4 to about 24 hours, such as from about 4 hours to about 10 hours, although other temperature and time combinations are envisioned. By way of a non-limiting example, the glass can be submerged in a KNO₃ bath, for example, at about 450° C. for about 6 hours to obtain a K-enriched layer which imparts a surface compressive stress.

According to various embodiments, the first and/or second glass substrates may have a compressive stress greater than about 100 MPa and a depth of layer of compressive stress (DOL) greater than about 10 microns. In further embodiments, the first and/or second glass substrates may have a compressive stress greater than about 500 MPa and a DOL greater than about 20 microns, or a compressive stress greater than about 700 MPa and a DOL greater than about 40 microns.

In non-limiting embodiments, the first and/or second glass substrates can have a thickness of less than or equal to about 2 mm, for example, ranging from about 0.1 mm to about 1.5 mm, from about 0.2 mm to about 1.1 mm, from about 0.3 mm to about 1 mm, from about 0.4 mm to about 0.9 mm, from about 0.5 mm to about 0.8 mm, or from about 0.6 mm to about 0.7 mm, including all ranges and subranges therebetween. According to various embodiments, the first and/or second glass substrate can have a thickness greater than 0.1 mm, such as greater than 0.2 mm, greater than 0.3 mm, greater than 0.4 mm, or greater than 0.5 mm, including all ranges and subranges therebetween. In certain non-limiting embodiments, the first glass substrate can have a thickness ranging from about 0.3 mm to about 0.4 mm, and the second glass substrate can have a thickness ranging from about 0.2 mm to about 0.4 mm.

The first and/or second glass substrate can, in various embodiments, be transparent or substantially transparent. As used herein, the term “transparent” is intended to denote that the glass substrate, at a thickness of approximately 1 mm, has a transmission of greater than about 80% in the visible region of the spectrum (420-700 nm). For instance, an exemplary transparent glass substrate may have greater than about 85% transmittance in the visible light range, such as greater than about 90%, or greater than about 95%, including all ranges and subranges therebetween. In certain embodiments, an exemplary glass substrate may have a transmittance of greater than about 50% in the ultraviolet (UV) region (200-410 nm), such as greater than about 55%, greater than about 60%, greater than about 65%, greater than about 70%, greater than about 75%, greater than about 80%, greater than about 85%, greater than about 90%, greater than about 95%, or greater than about 99% transmittance, including all ranges and subranges therebetween.

The first glass substrate can comprise a first surface and, in certain embodiments, the second glass substrate can comprise a second surface. The first and second surfaces may, in various embodiments, be parallel or substantially parallel. According to certain aspects of the disclosure, the first surface of the first glass substrate and the second surface of the second glass substrate can contact each other to form a sealing (or substrate) interface. An exemplary sealing interface 335 is depicted in FIG. 3. In these embodiments, the seal 370 can be formed directly between the first and second glass substrates.

For instance, a laser beam operating at a given wavelength can be directed at the sealing interface, e.g., onto the sealing interface, below the sealing interface, or above the sealing interface, to form a seal between the two substrates. Accordingly, the first and/or second glass substrate can be a sealing substrate, e.g., a substrate that absorbs light from the laser beam so as to form a weld or seal between the substrates. In certain embodiments, the first and/or second substrate may be heated by light absorption from the laser beam and may swell to form a glass-to-glass weld or hermetic seal. According to various embodiments, the first and/or second substrate may have an absorption greater than about 1 cm⁻¹ at the laser's given operating wavelength, for example, greater than about 5 cm⁻¹, greater than about 10 cm⁻¹, 15 cm⁻¹, greater than about 20 cm⁻¹, greater than about 30 cm⁻¹, greater than about 40 cm⁻¹, or greater than about 50 cm⁻¹, including all ranges and subranges therebetween. In other embodiments, one of the substrates can have an absorption less than about 1 cm⁻¹ at the laser's given operating wavelength, such as less than about 0.5 cm⁻¹, less than about 0.3 cm⁻¹, or less than about 0.1 cm⁻¹, including all ranges and subranges therebetween. In further embodiments, the first glass substrate can have an absorption of greater than 1 cm⁻¹ at the laser's operating wavelength and the second glass substrate can have an absorption of less than 1 cm⁻¹ at the laser's operating wavelength, or vice versa.

According to additional aspects of the disclosure, the first and/or second glass substrate can have an absorption of greater than about 10% at the laser's operating wavelength. For instance, the first and/or second glass substrate can absorb greater than about 15%, greater than about 20%, greater than about 25%, greater than about 30%, greater than about 35%, greater than about 40%, greater than about 45%, greater than about 50%, greater than about 55%, or greater than about 60% of the laser processing wavelength. In certain embodiments, the first and/or second substrate can have an initial absorption, at room temperature, of less than about 15%, such as ranging from about 2% to about 10%, or from about 5% to about 8%, of the laser wavelength. The absorption of the first and/or second substrate can, in various embodiments, increase with heating to greater than about 20%, such as greater than about 30%, greater than about 40%, greater than about 50%, greater than about 60%, or more.

In various non-limiting embodiments, the device can comprise a sealing layer disposed between the first and second glass substrates. In these embodiments, the sealing layer can contact the first surface of the first glass substrate and a surface of the second glass substrate. The sealing layer can be chosen, for example, from glass substrates having an absorption of greater than about 10% at the laser's operating wavelength and/or a relatively low glass transition temperature (T_{g}). The glass substrates can include, for instance, glass sheets, glass frits, glass powders, and glass pastes. According to various embodiments, the sealing layer can be chosen from borate glasses, phosphate glasses tellurite glasses, and chalcogenide glasses, for instance, tin phosphates, tin fluorophosphates, and tin fluoroborates. Suitable sealing glasses are disclosed, for instance, in U.S. patent application Ser. Nos. 13/777,584, 14/270,827, and 14/271,797, which are each incorporated herein by reference in their entireties.

In general, suitable sealing layer materials can include low T_{g} glasses and suitably reactive oxides of copper or tin. By way of non-limiting example, the sealing layer can comprise a glass with a T_{g} of less than or equal to about 400° C., such as less than or equal to about 350° C., about 300° C., about 250° C., or about 200° C., including all ranges and subranges therebetween. The glass can have, in various embodiments, an absorption at the laser's operating wavelength (at room temperature) of greater than about 10%, greater than about 15%, greater than about 20%, greater than about 25%, greater than about 30%, greater than about 35%, greater than about 40%, greater than about 45%, or greater than about 50%. The thickness of the sealing layer can vary depending on the application and, in certain embodiments, can range from about 0.1 microns to about 10 microns, such as less than about 5 microns, less than about 3 microns, less than about 2 microns, less than about 1 micron, less than about 0.5 microns, or less than about 0.2 microns, including all ranges and subranges therebetween.

Optionally, the sealing layer compositions can include one or more dopants, including but not limited to tungsten, cerium and niobium. Such dopants, if included, can affect, for example, the optical properties of the sealing layer, and can be used to control the absorption by the sealing layer of laser radiation. For instance, doping with ceria can increase the absorption by a low T_{g} glass barrier at laser processing wavelengths. Additional suitable sealing layer materials include laser absorbing low liquidus temperature (LLT) materials with a liquidus temperature less than or equal to about 1000° C., less than or equal to about 600° C., or less than or equal to about 400° C. In other embodiments, the sealing layer composition can be selected to lower the activation energy for inducing transient absorption by the first glass substrate and/or the second glass substrate.

Exemplary tin fluorophosphate glass compositions can be expressed in terms of the respective compositions of SnO, SnF₂ and P₂O₅ in a corresponding ternary phase diagram. Suitable UVA glass films can include SnO₂, ZnO, TiO₂, ITO, and other low melting glass compositions. Suitable tin fluorophosphates glasses can include 20-100 mol % SnO, 0-50 mol % SnF₂ and 0-30 mol % P₂O₅. These tin fluorophosphates glass compositions can optionally include 0-10 mol % WO₃, 0-10 mol % CeO₂ and/or 0-5 mol % Nb₂O₅. For example, a composition of a doped tin fluorophosphate starting material suitable for forming a glass sealing layer can comprise 35 to 50 mole percent SnO, 30 to 40 mole percent SnF₂, 15 to 25 mole percent P₂O₅, and 1.5 to 3 mole percent of a dopant oxide such as WO₃, CeO₂ and/or Nb₂O₅. A tin fluorophosphate glass composition according to one non-limiting embodiment can be a niobium-doped tin oxide/tin fluorophosphate/phosphorus pentoxide glass comprising about 38.7 mol % SnO, 39.6 mol % SnF₂, 19.9 mol % P₂O₅ and 1.8 mol % Nb₂O₅. Sputtering targets that can be used to form such a glass layer may include, expressed in terms of atomic mole percent, 23.04% Sn, 15.36% F, 12.16% P, 48.38% O and 1.06% Nb.

A tin phosphate glass composition according to another embodiment can comprise about 27% Sn, 13% P and 60% O, which can be derived from a sputtering target comprising, in atomic mole percent, about 27% Sn, 13% P and 60% O. As will be appreciated, the various glass compositions disclosed herein may refer to the composition of the deposited layer or to the composition of the source sputtering target. As with the tin fluorophosphates glass compositions, example tin fluoroborate glass compositions can be expressed in terms of the respective ternary phase diagram compositions of SnO, SnF₂ and B₂O₃. Suitable tin fluoroborate glass compositions can include 20-100 mol % SnO, 0-50 mol % SnF₂ and 0-30 mol % B₂O₃. These tin fluoroborate glass compositions can optionally include 0-10 mol % WO₃, 0-10 mol % CeO₂ and/or 0-5 mol % Nb₂O₅.

When the device comprises a sealing layer, the seal can be formed between the first and second glass substrates by way of the sealing layer. For instance, a laser beam operating at a given wavelength can be directed at the sealing layer (or sealing interface) to form a seal or weld between the two substrates. Without wishing to be bound by theory, it is believed that absorption of light from the laser beam by the sealing layer and induced transient absorption by the glass substrates can cause localized heating and melting of both the sealing layer and the glass substrates, thus forming a glass-to-glass weld between the two substrates. Exemplary glass-to-glass welds can be formed as described in pending and co-owned U.S. patent application Ser. Nos. 13/777,584, 14/270,827, and 14/271,797, which are each incorporated herein by reference in their entireties.

The first glass substrate may comprise a first surface and an array of cavities disposed on the first surface. Exemplary arrays of cavities are depicted in FIGS. 3-4. While these figures depict the cavities 315, 415 as having a substantially rectangular profile, it is to be understood that the cavities can have any given shape or size, as desired for a given application. For example, the cavities can have a square, circular, or oval shape, or an irregular shape, to name a few. Moreover, while the cavities are depicted as spaced apart in a substantially even fashion, it is to be understood that the spacing between the cavities can be irregular or in any pattern which can be chosen to match a given LED array pattern.

For example, a typical LED array for a backlit device can comprise an LED package having a height ranging from about 0.3 mm to about 5 mm, such as from about 0.5 mm to about 3 mm, or from about 1 mm to about 2 mm; a length ranging from about 0.5 mm to about 5 mm, such as from about 2 mm to about 3 mm, or about 1 mm; and a width ranging from about 0.3 mm to about 5 mm, such as from about 0.5 mm to about 3 mm, or from about 1 mm to about 2 mm, including all ranges and subranges therebetween. The LEDs can be spaced apart by a distance ranging from about 3 mm to about 50 mm, such as from about 5 mm to about 40 mm, from about 10 mm to about 30 mm, from about 12 mm to about 20 mm, or from about 15 mm to about 18 mm, including all ranges and subranges therebetween. Of course, the size and spacing of the LED array can vary depending, e.g., on the brightness and/or total power of the display. Accordingly, the size and spacing of the cavities can likewise vary to match or substantially match a given LED array.

The cavities on the first surface of the first glass substrate can have any given depth, which can be chosen as appropriate, e.g., for the type and/or amount of color-converting element to be placed in the cavities. By way of non-limiting embodiment, the cavities on the first surface can extend to a depth of less than about 1 mm, such as less than about 0.5 mm, less than about 0.4 mm, less than about 0.3 mm, less than about 0.2 mm, less than about 0.1 mm, less than about 0.05 mm, or less than about 0.02 mm, including all ranges and subranges therebetween. It is envisioned that the array of cavities can comprise cavities having the same or different depths, the same or different shapes, and/or the same or different sizes.

At least one cavity in the array of cavities can comprise at least one color-converting element. As used herein the term “color-converting element” and variations thereof can denote, for example, elements capable of receiving light and converting the light into a different, e.g., longer wavelength. For instance, the color-converting elements or “color converters” may be chosen from quantum dots, fluorescent dyes, e.g., coumarin and rhodamine, to name a few, and/or phosphors, e.g., red, green, and/or blue phosphors. According to various embodiments, the color-converting elements may be chosen from green and red phosphors. For example, when irradiated with blue, UV, or near-UV light, a phosphor may convert the light into longer red, yellow, green, or blue wavelengths. Further, exemplary color-converting elements may comprise quantum dots emitting in the red and green wavelengths when irradiated with blue, UV, or near-UV light.

According to additional embodiments, a surface of the first or second glass substrate can comprise at least one cavity containing at least one component chosen from light emitting structures and/or color-converting elements. For example, the at least one cavity can comprise a laser diode (LD), light emitting diode (LED), organic light emitting diode (OLED), and/or one or more quantum dots (QDs). In certain embodiments, the at least one cavity may comprise at least one LED and/or at least one QD.

The first and second glass substrates can, in various embodiments be sealed together as disclosed herein, to produce a glass-to-glass weld. In certain embodiments, the seal may be a hermetic seal, e.g., forming one or more air-tight and/or waterproof pockets in the device. For example, at least one cavity containing at least one color-converting element can be hermetically sealed such that the cavity is impervious or substantially impervious to water, moisture, air, and/or other contaminants. By way of non-limiting example, a hermetic seal can be configured to limit the transpiration (diffusion) of oxygen to less than about 10⁻² cm³/m²/day (e.g., less than about 10⁻³/cm³/m²/day), and limit transpiration of water to about 10⁻² g/m²/day (e.g., less than about 10⁻³, 10⁻⁴, 10⁻⁵, or 10⁻⁶ g/m²/day). In various embodiments, a hermetic seal can substantially prevent water, moisture, and/or air from contacting the components protected by the hermetic seal.

The sealed devices disclosed herein can thus comprise an array of sealed cavities which can be spaced apart as desired, at least a portion of which can comprise at least one color-converting element, such as quantum dots. This configuration can make it possible to provide an optical component for a backlit device, such as an LCD device, which can provide color-converting elements in areas adjacent LED components, without material waste of the color-converting elements in areas adjacent “dead” spaces (e.g., areas not adjacent LED components). Alternatively, the sealed devices disclosed herein can comprise a single cavity which can comprise a light emitting structure and/or a color-converting element.

According to certain aspects, the total thickness of the sealed device can be less than about 2 mm, such as less than about 1.5 mm, less than about 1 mm, or less than about 0.5 mm, including all ranges and subranges therebetween. For example, the thickness of the sealed device can range from about 0.3 mm to about 1 mm, such as from about 0.4 mm to about 0.9 mm, from about 0.5 mm to about 0.8 mm, or from about 0.6 mm to about 0.7 mm, including all ranges and subranges therebetween.

While the embodiments depicted in FIGS. 2-4 contemplate a one-dimensional (e.g., single row) of cavities and LEDs, it is to be understood that the sealed device disclosed herein can also be used for two-dimensional arrays (e.g., more than one row and/or extending in more than one direction). The height and length dimensions of the sealed device can therefore vary as desired to suit the chosen 1D or 2D LED array. For instance, the sealed device can have a length ranging from about 0.3 mm to about 1.5 m, such as from about 1 mm to about 1 m, from about 1 cm to about 500 cm, from about 10 cm to about 250 cm, or from about 50 cm to about 100 cm, including all ranges and subranges therebetween. The height of the sealed device can likewise range from about 0.3 mm to about 1.5 m, such as from about 1 mm to about 1 m, from about 1 cm to about 500 cm, from about 10 cm to about 250 cm, or from about 50 cm to about 100 cm, including all ranges and subranges therebetween.

The sealed devices disclosed herein may be used in various display devices including, but not limited to backlit displays such as LCDs, which can comprise various additional components. One or more light sources may be used, for example light-emitting diodes (LEDs) or cold cathode fluorescent lamps (CCFLs). Conventional LCDs may employ LEDs or CCFLs packaged with color converting phosphors to produce white light. According to various aspects of the disclosure, display devices employing the disclosed sealed devices may comprise at least one light source emitting blue light (UV light, approximately 200-410 nm), such as near-UV light (approximately 300-410 nm).

Exemplary LCD devices may further comprise various conventional components, such as a reflector, a light guide, a diffuser, one or more prism films, a reflecting polarizer, one or more linear polarizers, a thin-film-transistor (TFT) array, a liquid crystal layer, and/or a color filter. In various embodiments, a reflector can be used to send recycled light back through the light guide. The reflector may reflect, e.g., up to about 85% of the light and may randomize its angular and polarization properties. The light may then pass through a light guide, which can direct light toward the LCD. A diffuser may be used to improve the spatial uniformity of the light. A first prism film may reflect light at high angles back towards the reflector for recycling and may serve to concentrate light in the forward direction. A second prism film may be positioned orthogonal to the first prism film and may function in the same manner but along the orthogonal axis.

A reflecting polarizer may reflect light of one polarization back towards the reflector for recycling and may serve to concentrate light into a single polarization. A first linear polarizer may be employed to permit passage of only light with a single polarization. A TFT array may comprise active switching elements that permit voltage addressing of each sub-pixel of the display. A liquid crystal layer may comprise an electrooptic material, the structure of which rotates upon application of an electric field, causing a polarization rotation of any light passing through it. A color filter may comprise an array of red, green, and blue filters aligned with the sub-pixels that may produce the display color. Finally, a second linear polarizer may be used to filter any non-rotated light.

Methods

Disclosed herein are methods for making a sealed device, the methods comprising placing at least one color-converting element in at least one cavity in an array of cavities on a first surface of a first glass substrate; bringing a second surface of a second glass substrate into contact with the first surface of the first glass substrate to form a sealing interface; and directing a laser beam operating at a predetermined wavelength onto the sealing interface to form a seal between the first substrate and the second substrate, the seal extending around the at least one cavity containing the at least one color-converting element.

Also disclosed herein are methods for making a sealed device, the methods comprising placing at least one color-converting element in at least one cavity in an array of cavities on a first surface of a first glass substrate; bringing a sealing layer into contact with the first surface of the first glass substrate; bringing a second glass substrate into contact with the sealing layer such that the sealing layer is disposed between the first and second glass substrates; and directing a laser beam operating at a predetermined wavelength onto the sealing layer to form a seal between the first substrate and the second substrate, the seal extending around the at least one cavity containing the at least one color-converting element.

The at least one color-converting element can be introduced into, or placed in, at least one cavity in the array of cavities using any method known in the art. For example, the color-converting elements can be deposited, printed, or patterned into the respective cavities, depending on the size and orientation of the cavities. According to various embodiments, the color-converting elements placed in the cavities are sealed, e.g., hermetically sealed in the cavities to form discrete, spaced-apart pockets of color-converting elements.

Also disclosed herein are methods for making a sealed device, the methods comprising brining a first surface of a first glass substrate and a second surface of a second glass substrate into contact with a sealing layer to form a sealing interface, directing a first laser operating at a first predetermined wavelength onto the sealing interface to form a hermetic seal between the first and second glass substrates, and directing a second laser operating at a second predetermined wavelength onto the sealing interface to form a non-hermetic seal between the first and second glass substrates.

Still further disclosed herein are methods for making a sealed device, the methods comprising bringing a first surface of a first glass substrate and a second surface of a second glass substrate into contact with a sealing layer to form a sealing interface, directing a laser operating at a predetermined wavelength onto the sealing interface to form at least one seal line between the first glass substrate and the second glass substrate, the at least one seal line defining at least two sealed regions; and separating the at least two sealed regions along at least one separation line, wherein the at least one seal line and the at least one separation line do not intersect.

According to the methods disclosed herein, the first and second glass substrates, and optionally the sealing layer, can be brought into contact to form a sealing interface. The sealing interface is referred to herein as the point of contact between the first surface of the first glass substrate and the second surface of the second glass substrate, or the point of contact between these surfaces with the sealing layer, e.g., the meeting of the surfaces to be joined by the weld or seal. The substrates and/or sealing layer may be brought into contact by any means known in the art and may, in certain embodiments, be brought into contact using force, e.g., an applied compressive force. By way of a non-limiting example, the substrates may be arranged between two plates and pressed together. In certain embodiments, clamps, brackets, vacuum chucks, and/or other fixtures may be used to apply a compressive force so as to ensure good contact at the sealing interface. According to various non-limiting embodiments, two silica plates may be used, although plates comprising other materials are envisioned. Advantageously, if plates are used, the plate adjacent the laser can be transparent and/or can have minimal absorption at the laser wavelength, so as to ensure that the laser beam light is concentrated at the sealing interface. The opposing plate (e.g., the plate distal from the laser can be transparent in some embodiments, but can also be constructed of any suitable material.

In some embodiments, the method can comprises forming a first sealing layer on a sealing (e.g., first) surface of the first glass substrate and/or forming a second sealing layer on a sealing (e.g., second) surface of the second glass substrate, placing at least a portion of the sealing layers and/or sealing surfaces in physical contact, and heating the sealing layer(s) to locally melt the sealing layer(s) and the sealing surfaces to form a glass-to-glass weld between the first and second glass substrates. According to various embodiments, sealing using a low melting temperature glass layer can be accomplished by the local heating, melting and then cooling of both the sealing layer and the glass substrate material located proximate to the sealing interface.

Embodiments of the present disclosure also provide a laser sealing process, e.g., laser welding, diffusion welding, etc., that relies upon color center formation within the glass substrates due to extrinsic color centers, e.g., impurities or dopants, or intrinsic color centers inherent to the glass, at an incident laser wavelength, combined with an exemplary absorbing sealing layer. Welds using these materials can provide visible transmission with sufficient UV absorption to initiate steady state gentle diffusion welding. These materials can also provide transparent laser welds having localized sealing temperatures suitable for diffusion welding. Such diffusion welding can result in low power and temperature laser welding of the respective glass substrates and can produce superior transparent welds with efficient and fast welding speeds. Exemplary laser welding processes according to embodiments of the present disclosure can also rely upon photo-induced absorption properties of glass beyond color center formation to include temperature induced absorption.

A laser can be used to form the seal between the first and second glass substrates and may be chosen from any suitable laser known in the art for glass substrate welding. For example, the laser may emit light at UV (˜350-410 nm), visible (˜420-700 nm), or NIR (˜750-1400 nm) wavelengths. In certain embodiments, a high-repetition pulsed UV laser operating at about 355 nm, or any other suitable UV wavelength, may be used. In other embodiments, a continuous wave laser operating at about 532 nm, or any other suitable visible wavelength, may be used. In further embodiments, a near-infrared laser operating at about 810 nm, or any other suitable NIR wavelength, may be used. According to various embodiments, the laser may operate at a predetermined wavelength ranging from about 300 nm to about 1600 nm, such as from about 350 nm to about 1400 nm, from about 400 nm to about 1000 nm, from about 450 nm to about 750 nm, from about 500 nm to about 700 nm, or from about 600 nm to about 650 nm, including all ranges and subranges therebetween.

According to various embodiments, the laser beam can operate at an average power greater than about 3 W, for example, ranging from about 6 W to about 15 kW, such as from about 7 W to about 12 kW, from about 8 W to about 11 kW, or from about 9 W to about 10 kW, including all ranges and subranges therebetween. In additional embodiments embodiments, the laser beam can have an average power ranging from about 0.2 W to about 50 W, such as from about 0.5 W to about 40 W, from about 1 W to about 30 W, from about 2 W to about 25 W, from about 3 W to about 20 W, from about 4 W to about 15 W, from about 5 W to about 12 W, from about 6 W to about 10 W, or from about 7 W to about 8 W, including all ranges and subranges therebetween.

The laser may operate at any frequency and may, in certain embodiments, may operate in a quasi-continuous or continuous manner. In other embodiments, the laser may operate in burst mode having a plurality of bursts with a time separation between individual pulses in a burst at about 50 kHz or between 100 kHz to 1 MHz, or between 10 kHz and 10 MHz, including all ranges and subranges therebetween. In some non-limiting single pulse embodiments, the laser may have a frequency or time separation between adjacent pulses (repetition rate) ranging from about 1 kHz to about 5 MHz, such as from about 1 kHz to about 30 kHz, or from about 200 kHz to about 1 MHz, for example, from about 1 MHz to about 3 MHz, including all ranges and subranges therebetween. According to various embodiments, the laser may have a repetition rate greater than about 1 MHz.

The duration or pulse width of the pulse may vary, for example, the duration may be less than about 50 ns in certain embodiments. In other embodiments, the pulse width or duration may be less than about 10 ns, such as less than about 1 ns, less than about 10 ps, or less than about 1 ps. Other exemplary lasers and methods therefor to form glass-to-glass welds and other exemplary seals are described in pending and co-owned U.S. patent application Ser. Nos. 13/777,584, 14/270,827, and 14/271,797, which are each incorporated herein by reference in their entireties.

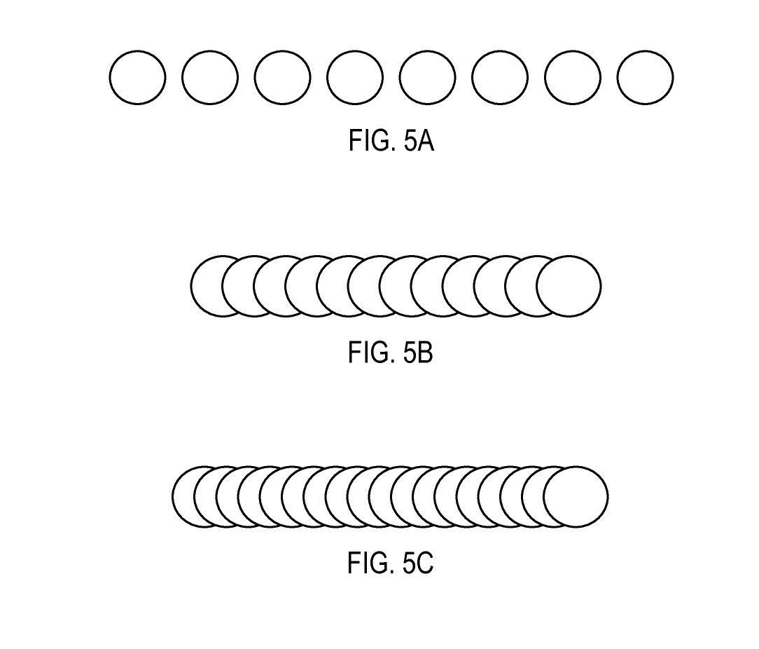

The methods disclosed herein can be employed to create hermetically and non-hermetically sealed packages, e.g., by tuning the weld morphology or properties. For example, as shown in FIGS. 5A-C, various weld patterns can be created using pulsed or modulated continuous wave (CW) lasers. Pulsed lasers can include any lasers emitting energy in the form of pulses or bursts rather than a continuous wave. A pulsed laser can periodically emit pulses of light/energy in a short time period, otherwise referred to as a “pulse train.” Continuous wave (CW) lasers can also be used with modulation, e.g., by turning the laser on and off at desired intervals.

According to various embodiments, the beam may be directed at and focused on the sealing interface, below the sealing interface, or above the sealing interface, such that the beam spot diameter on the interface may be less than about 1 mm. For example, the beam spot diameter may be less than about 500 microns, such as less than about 400 microns, less than about 300 microns, or less than about 200 microns, less than about 100 microns, less than 50 microns, or less than 20 microns, including all ranges and subranges therebetween. In some embodiments, the beam spot diameter may range from about 10 microns to about 500 microns, such as from about 50 microns to about 250 microns, from about 75 microns to about 200 microns, or from about 100 microns to about 150 microns, including all ranges and subranges therebetween.

The laser beam may be scanned or translated along the substrates, or the substrates can be translated relative to the laser, using any predetermined path to produce any pattern, such as a square, rectangular, circular, oval, or any other suitable pattern or shape, for example, to hermetically or non-hermetically seal one or more cavities in the device. The translation speed at which the laser beam (or substrate) moves along the interface may vary by application and may depend, for example, upon the composition of the first and second substrates and/or the focal configuration and/or the laser power, frequency, and/or wavelength. In certain embodiments, the laser may have a translation speed ranging from about 1 mm/s to about 1000 mm/s, for example, from about 10 mm/s to about 500 mm/s, or from about 50 mm/s to about 700 mm/s, such as greater than about 100 mm/s, greater than about 200 mm/s, greater than about 300 mm/s, greater than about 400 mm/s, greater than about 500 mm/s, or greater than about 600 mm/s, including all ranges and subranges therebetween.

The speed at which the laser (or article) is translated is referred to herein as the translation speed (V). The spot diameter of the laser beam (D) at the sealing interface may also affect the strength, pattern, and/or morphology of the laser weld. Finally, the repetition rate (rₚ) for a pulsed laser or the modulation speed (rₘ) for a CW laser can affect the resulting laser weld line. In certain embodiments, a pulsed laser may be operated at a translation speed (V) that is greater than the product of the spot diameter of the laser beam at the sealing interface and the repetition rate of the laser beam (rₚ), according to formula (1):

V/(D*rₚ)>1 (1)

Similarly, a modulated CW laser can be operated at a translation speed (V) that is greater than the product of the spot diameter of the laser beam at the sealing interface (D) and the modulation speed of the laser beam (rₘ), according to formula (1′):

V/(D*rₘ)>1 (1′)

Of course, for a given translation speed, the spot diameter D, repetition rate rₚ, and/or modulation speed rₘ can also be varied to satisfy formulae (1) or (1′). A laser operating under these parameters can produce a non-overlapping laser weld comprising individual “spots” as illustrated in FIG. 5A. For instance, the time between laser pulses (1/rₚ or 1/rₘ) can be greater than the average amount of time the laser spends on a single weld spot, also referred to as the “dwell time” (D/V). In some embodiments, V/(D*rₚ) or V/(D*rₘ) can range from about 1.05 to about 10, such as from about 1.1 to about 8, from about 1.2 to about 7, from about 1.3 to about 6, from about 1.4 to about 5, from about 1.5 to about 4, from about 1.6 to about 3, from about 1.7 to about 2, or from about 1.8 to about 1.9, including all ranges and subranges therebetween. Such a weld pattern may be used, for example, to produce a non-hermetic seal according to various embodiments of the disclosure.

In other embodiments, a pulsed laser may be operated at a translation speed (V) that is less than or equal to the product of the spot diameter (D) and the repetition rate (rₚ), according to formula (2):

V/(D*rₚ)≦1 (2)

Similarly, a modulated CW laser can be operated at a translation speed (V) that is less than or equal to the product of the spot diameter of the laser beam at the sealing interface (D) and the modulation speed of the laser beam (rₘ), according to the following formula (2′):

V/(D*rₘ)≦1 (2′)

Of course, for a given translation speed, the spot diameter D, repetition rate rₚ, and/or modulation speed rₘ can also be varied to satisfy formulae (2) or (2′). Operating under such parameters can produce an overlapping laser weld comprising contiguous “spots” as illustrated in FIG. 5B or approaching a continuous line as illustrated in FIG. 5C (e.g., as rₘ increases to infinity). For instance, the time between laser pulses (1/rₚ or 1/rₘ) can be less than or equal to the “dwell time” (D/V). In some embodiments, V/(D*rₚ) or V/(D*rₘ) can range from about 0.01 to about 1 such as from about 0.05 to about 0.9, from about 0.1 to about 0.8, from about 0.2 to about 0.7, from about 0.3 to about 0.6, or from about 0.4 to about 0.5, including all ranges and subranges therebetween. These weld patterns may be used, for example, to produce a hermetic seal according to various embodiments of the disclosure.

According to various embodiments disclosed herein, the laser wavelength, pulse duration, repetition rate, average power, focusing conditions, and other relevant parameters may be varied so as to produce an energy sufficient to weld the first and second substrates together, either directly or by way of a sealing layer. It is within the ability of one skilled in the art to vary these parameters as necessary for a desired application. In various embodiments, the laser fluence (or intensity) is below the damage threshold of the first and/or second substrate, e.g., the laser operates under conditions intense enough to weld the substrates together, but not so intense as to damage the substrates. In certain embodiments, the laser beam may operate at a translation speed that is less than or equal to the product of the diameter of the laser beam at the sealing interface and the repetition rate of the laser beam.

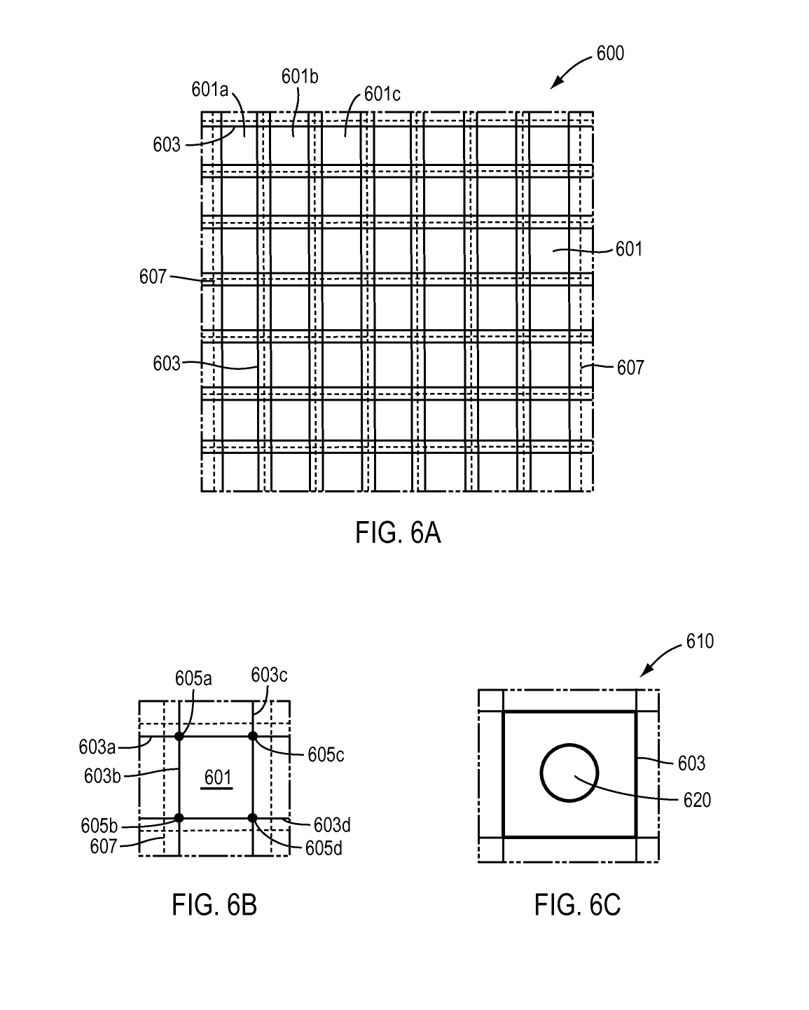

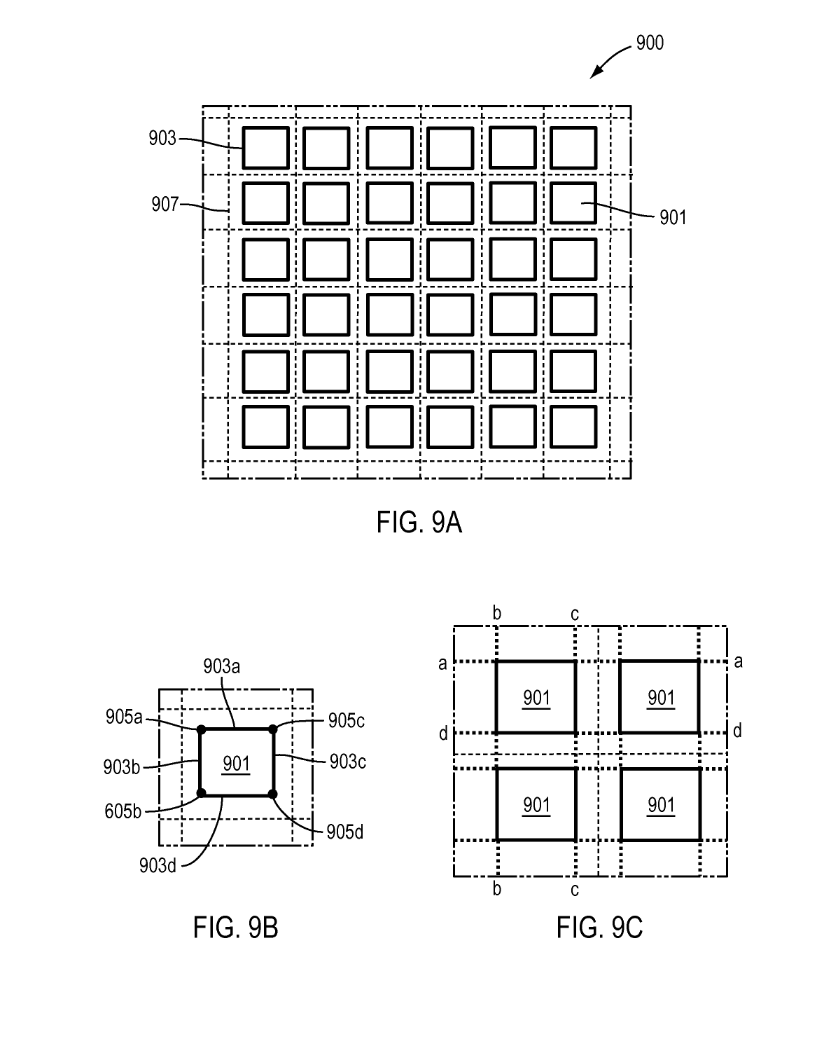

The laser can be translated along the substrates (or vice versa) to create any desired pattern. For example, the laser can be translated to produce the non-limiting pattern depicted in FIG. 6A. Specifically, the laser may be focused on or near the sealing interface of article 600 to produce laser weld lines 603 (solid lines). These laser weld lines may overlap to form a grid of laser weld sealed sections 601, wherein each laser weld line forms a portion of the seal extending around each sealed section 601. For example weld lines 603 may form all or a portion of the seal around sections 601a, 601b, 601c, and so forth. As discussed in greater detail below, the individual sections 601 can then be separated from the article 600 by mechanical separation, e.g., cutting, along separation or dicing lines 607 (dashed lines). In the depicted non-limiting embodiment, the weld lines 603 and separation lines may cross one another or, as discussed with respect to FIGS. 9-11, the weld lines and separation lines may not intersect.

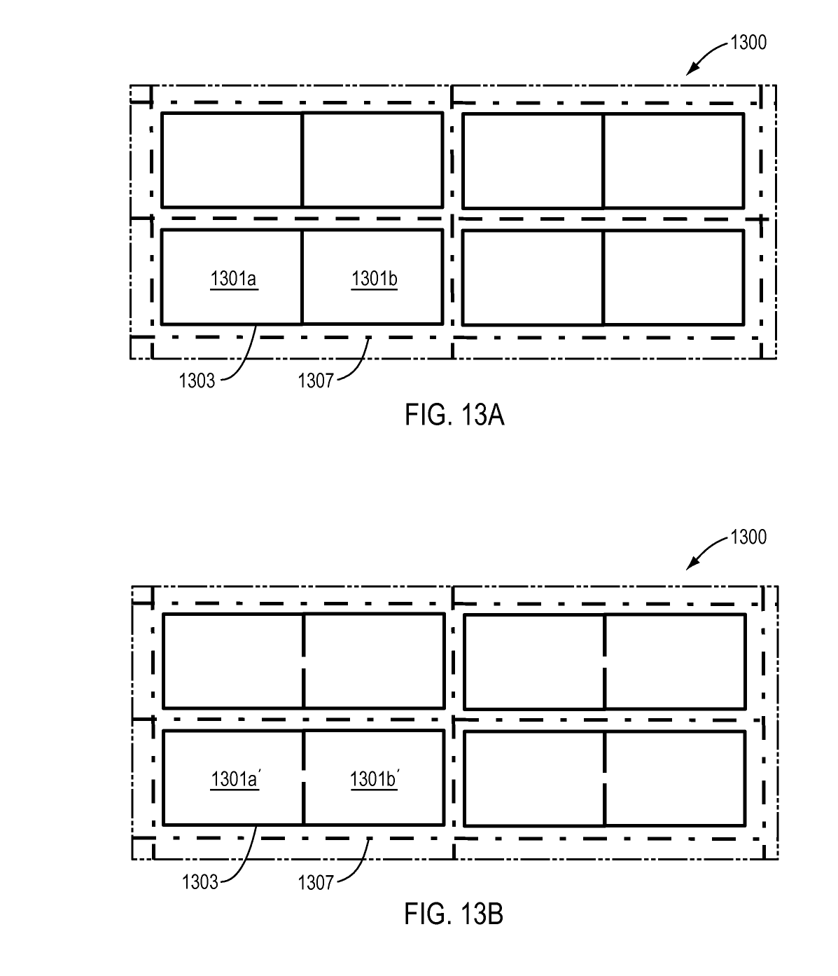

Referring to FIG. 6B, which depicts an exemplary sealed section 101 that has been separated from the article 600 depicted in FIG. 6A, the seal of each section may be defined by four laser weld lines 603a, 603b, 603c, 603d which intersect at four separate points 605a, 605b, 605c, 605d. According to various embodiments, the laser weld lines are free or substantially free of defects at the intersecting points (106a, b, c, d) and/or the non-intersecting portions of the weld lines. After singulation along the separation lines 607, one or more sealed devices 610 depicted in FIG. 6C can be produced, these devices optionally comprising a workpiece 620 sealed therein, such as a LD, LED, OLED, QDs, or the like. Alternatively, although not illustrated in FIGS. 6A-C, the article 600 may be separated into two or more pieces, each piece comprising one or more sealed sections 601, such as two, three, four, five, or more sealed sections per separated piece (see, e.g., FIG. 13A).

Without wishing to be bound by theory, it is believed that the methods disclosed herein produce weld lines that may overlap without causing any substantial defects that might otherwise compromise the strength and/or hermeticity of the seal. It is further noted that the sealing methods disclosed herein differ from prior art frit sealing methods in which overlap of the laser weld lines (e.g., exposing the frit twice to laser energy) can damage the frit and compromise the hermeticity of the seal. Of course, while FIGS. 6A-C depict square seals formed by four overlapping weld lines 603, it is to be understood that seals having any shape can be formed by any number of weld lines. Moreover, an article need not comprise the same size and/or shape of sealed sections as depicted in FIG. 6A although, in some embodiments, an article can comprise a plurality of sealed sections of substantially the same size and/or shape.

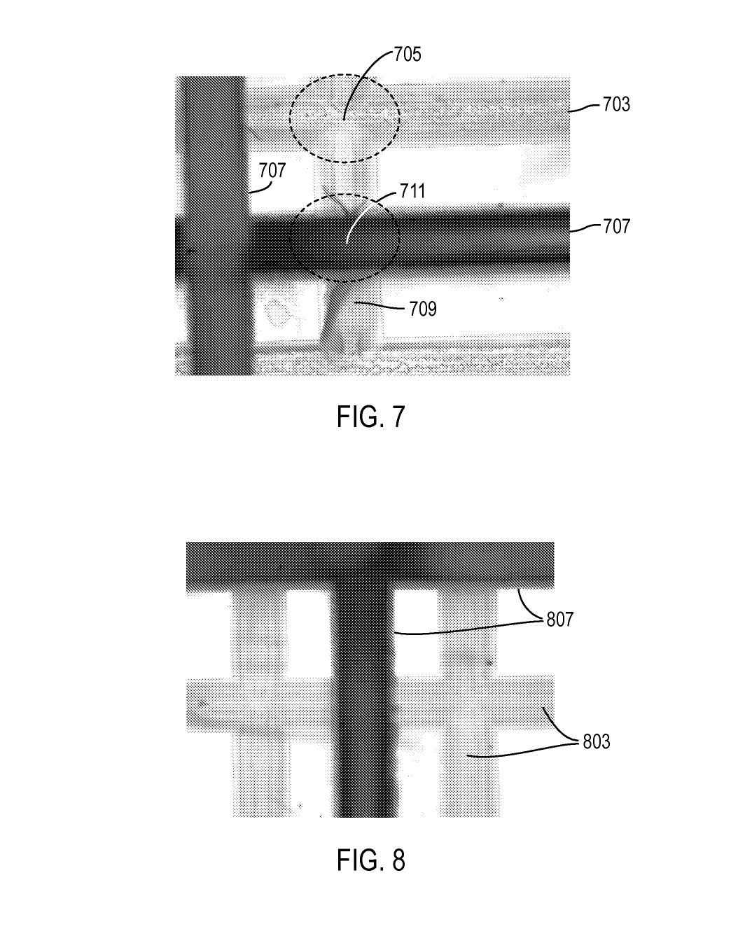

FIG. 7 depicts an article having weld lines 703, wherein the article is cut along separation or dicing lines 707 that intersect the weld lines 703. As shown, singulation or separation along line 707 may result in the formation of one or more defects 709 in the laser weld line 703 proximate the point of intersection 111 between the separation line 707 and the laser weld line 703. Such defects may propagate along the weld lines 703 and could eventually compromise the integrity of a sealed section. For example, the defects 709 in FIG. 7 may spread to the point of intersection 705 between laser weld lines 703. According to various embodiments, it may be desirable to weld two glass substrates to form multiple sealed sections and to separate or singulate those sections without the formation of defects in the weld lines and/or the seal around each section. For example, FIG. 8 illustrates a glass article having weld lines 803, cut along separation or dicing lines 807 that do not comprise such defects.

Seal defects can be reduced or eliminated, in some non-limiting embodiments, by creating non-intersecting weld lines and separation lines on a glass article to produce multiple sealed devices. These non-limiting embodiments will be discussed with respect to FIGS. 9-11. FIG. 9A depicts an article 900 comprising a plurality of weld lines 903 (solid lines) defining a plurality of sealed sections 901, which can be singulated by cutting along separation lines 907 (dashed lines). As illustrated, separation lines 907 may not intersect with weld lines 903 according to these and other non-limiting embodiments. Referring to FIG. 9B, which depicts an exemplary sealed section 901 that has been separated from the article 900 depicted in FIG. 9A, the seal of each section may be defined by four laser weld lines 903a, 903b, 903c, 903d which intersect at four separate points 905a, 905b, 905c, 905d. According to various embodiments, the laser weld lines are free or substantially free of defects at the intersecting points (905a, b, c, d) and/or the non-intersecting portions of the weld lines.

The pattern depicted in FIG. 9A can be formed by various non-limiting methods. For example, a laser can be translated along the glass substrate in a predetermined path, e.g., a straight line, and modulated (or turned on and off) to form a segmented pattern. For example, as shown in FIG. 9C, which shows an enlarged portion of the article depicted in FIG. 9A, a laser can be translated along a predetermined path (a, b, c, d) to form laser welded sections (represented by solid lines) and gaps (represented by dashed lines). The gaps can be formed, for instance, by modulating the laser to form the desired pattern. Alternatively, the laser can be operated in pulsed or continuous mode, with or without modulation, and blocking masks can be placed on the glass substrate to prevent absorption of energy from the laser in the predetermined locations. Suitable blocking masks can comprise, for example, reflective materials such as metal films, e.g., silver, platinum, gold, copper, and the like.

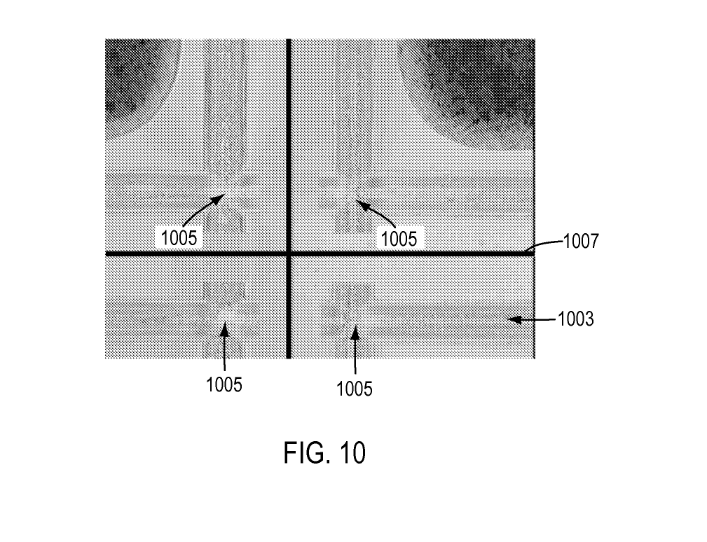

While FIGS. 9A-C depict square seals formed from four weld lines 903, it is to be understood that any number of weld lines 903 can be used to form seals of any size or shape. Moreover, an article need not comprise the same size and/or shape of sealed sections as depicted in FIG. 9A although, in some embodiments, a glass article can comprise a plurality of sealed sections of substantially the same size and/or shape. Finally, while FIGS. 9A-C depict weld lines 903 that do not extend past intersecting points 905(a, b, c, d) it is to be understood that the weld lines may extend, to some degree, past the intersection point 905, depending on the parameters of the laser, e.g., modulation speed, repetition rate, translation speed, and/or any masking used on the glass article. FIG. 10 depicts a glass article having weld lines 1003 that intersect at (and extend past) points 1005, wherein the article is cut along separation or dicing lines 1007 that do not intersect the weld lines 1003.

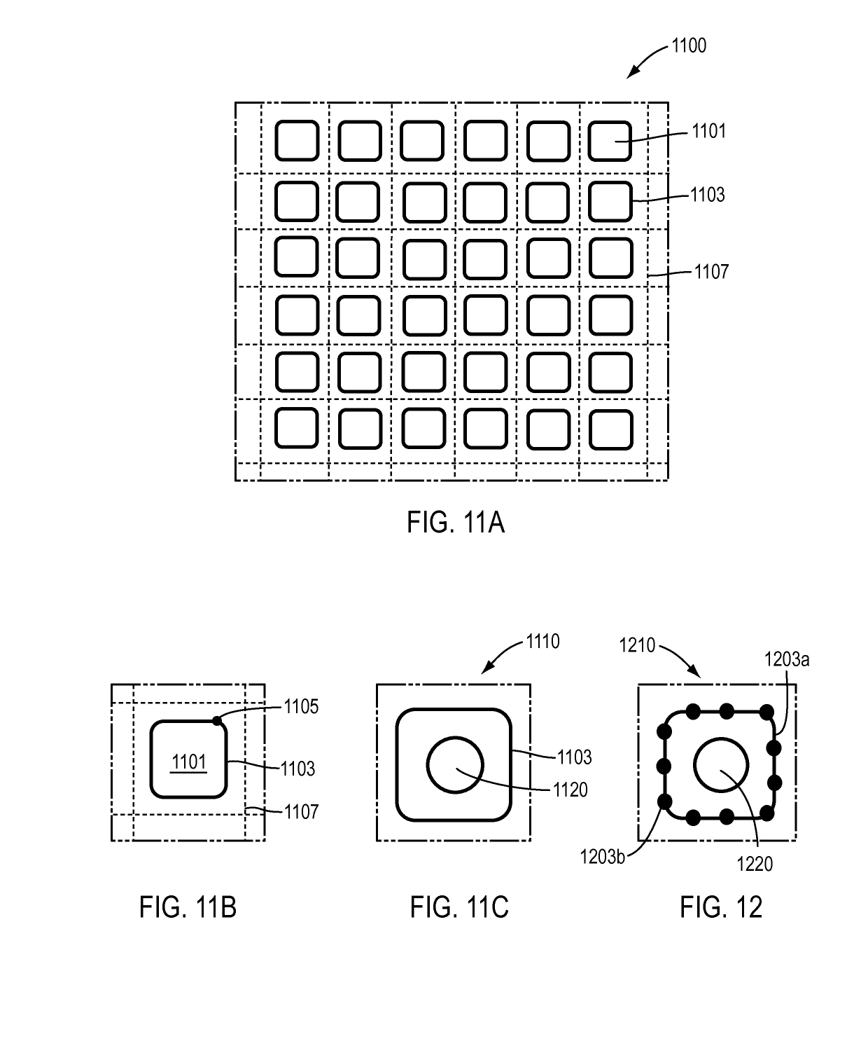

In yet another embodiment, the laser can be operated to produce an article having the sealing pattern depicted in FIG. 11A. The depicted pattern can be achieved, for example, by individually creating each laser weld line 1103 to produce each sealed section 1101. For example, the laser can be translated to produce a weld line 1103 in the form of a continuous, discrete loop as depicted in FIG. 11A. The laser can then be translated to a different location to form another discrete loop. The continuous loop can have any desired shape, such as a circle, oval, square with rounded corners, rectangle with rounded corners, and the like. In various embodiments, the laser weld lines 1103 may be formed in loops not intersecting the separation or dicing lines 1107. As shown in FIG. 11B, such a continuous loop can be formed with a single laser weld line comprising only one point 1105 at which laser weld overlaps. According to various embodiments, the continuous loop pattern depicted in FIGS. 11A-B may be advantageous due to the presence of a single point of intersection, as compared to more than one intersection (e.g., as shown in FIGS. 6A-B and 9A-C). After singulation along the separation lines 1107, one or more sealed devices 1110 depicted in FIG. 11C can be produced, these devices optionally comprising a workpiece 1120 sealed therein, such as a LD, LED, OLED, QDs, or the like. Alternatively, although not illustrated in FIGS. 11A-C, the article 1100 may be separated into two or more pieces, each piece comprising one or more sealed sections 1101, such as two, three, four, five, or more sealed sections per separated piece (see, e.g., FIG. 13A).

As depicted in FIG. 13A, an article 1300 may be sealed along weld lines 1303 and singulated along separation lines 1307 to produce one or more sealed devices comprising two or more sealed compartments. For example, a sealed device comprising two sealed compartments 1301a and 1301b can be produced. Of course, the depicted embodiments is not limiting and sealed devices comprising three or more sealed compartments, e.g., four or more, five or more, and so on, can be similarly produced and are intended to fall within the scope of the disclosure. By way of a non-limiting example, an article can be sealed and singulated to create a plurality of sealed devices depicted in FIG. 3 or FIG. 4. Sealed devices comprising a plurality of sealed cavities can be useful in a variety of applications, for example, devices comprising different color-converting elements in each cavity.

In some embodiments, it is possible that the two or more sealed compartments 1301a and 1301b can comprise the same or different types of color-converting elements, e.g., OLEDs or QDs emitting different wavelengths. For example, in some embodiments, a cavity can comprise color-converting elements emitting both green and red wavelengths, to produce a red-green-blue (RGB) spectrum in the cavity. However, according to other embodiments, it is possible for an individual cavity to comprise only color-converting elements emitting the same wavelength, such as a cavity comprising only green emitting elements or a cavity comprising only red emitting elements, which can optionally be paired with an empty cavity (e.g. emitting blue light). Using such a configuration, sealed devices can comprise individual cavities separately emitting a single color which, together, can produce the RGB spectrum.

As depicted in FIG. 13B, an article 1300 may be sealed along weld lines 1303 and singulated along separation lines 1307 to produce one or more sealed devices comprising two or more cavities which are connected or in communication with one another. For example, a sealed device comprising two connected cavities 1301a′ and 1301b′ can be produced. Of course, the depicted embodiments is not limiting and sealed devices comprising three or more connected cavities, e.g., four or more, five or more, and so on, can be similarly produced and are intended to fall within the scope of the disclosure. As depicted in FIG. 13B, the cavities can be separated by a partial seal line for partial connectivity between the cavities, or the region between the two cavities can be unsealed, without limitation. Sealed devices comprising a plurality of interconnected cavities can be useful in a variety of applications, for example, devices comprising an electronic, a light emitting structure, and/or a color-converting element, which may further benefit from the presence of another component, such as a getter or like component. In some embodiments, a getter may be placed in a cavity 1301a′ interconnected with another cavity 1301b′ to assist with the maintenance of a vacuum within the sealed device and/or to remove any residual gas within the device.

In additional embodiments, the methods disclosed herein can be used to form a combination of hermetic and non-hermetic seals, such as to reinforce a weaker hermetic seal by combining it with a stronger non-hermetic seal. For example, referring to FIG. 12, a first hermetic seal 1203a can be created to seal two substrates together to form an article 1210 (optionally encapsulating a workpiece 1220), and a second non-hermetic seal 1203b can subsequently be created, e.g., substantially along the same seal path as the hermetic seal 1203a, to form a reinforced, combined seal. In some embodiments, the hermetic and non-hermetic seals may substantially overlap or be substantially coextensive. In other embodiments, the hermetic and non-hermetic seals may be adjacent or proximate one another. Hermetic and non-hermetic seals can be formed as disclosed herein, using any desired combination of laser parameters. For example, a first laser operating at a first predetermined wavelength can be used to create a hermetic seal (e.g., according to the formula V/(D*r)≦1). A second laser operating at a second predetermined wavelength can subsequently be used to form a non-hermetic seal (e.g., according to the formula V/(D*r)>1). In some embodiments, a non-hermetic seal can be formed first, followed by a hermetic seal. According to additional embodiments, the first and second lasers may be identical or different and may operate at identical or different wavelengths. Of course, while FIG. 12 depicts a particular pattern and/or spacing for seals 1203a and 1203b, it is to be understood that any combination of pattern, spacing, size, and the like, can be used to create a combined seal for any given application.

It will be appreciated that the various disclosed embodiments may involve particular features, elements or steps that are described in connection with that particular embodiment. It will also be appreciated that a particular feature, element or step, although described in relation to one particular embodiment, may be interchanged or combined with alternate embodiments in various non-illustrated combinations or permutations.

It is also to be understood that, as used herein the terms “the,” “a,” or “an,” mean “at least one,” and should not be limited to “only one” unless explicitly indicated to the contrary. Thus, for example, reference to “a light source” includes examples having two or more such light sources unless the context clearly indicates otherwise. Likewise, a “plurality” or an “array” is intended to denote “more than one.” As such, a “plurality” or “array” of cavities includes two or more such elements, such as three or more such cavities, etc.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a device that comprises A+B+C include embodiments where a device consists of A+B+C and embodiments where a device consists essentially of A+B+C.

It will be apparent to those skilled in the art that various modifications and variations can be made to the present disclosure without departing from the spirit and scope of the disclosure. Since modifications combinations, sub-combinations and variations of the disclosed embodiments incorporating the spirit and substance of the disclosure may occur to persons skilled in the art, the disclosure should be construed to include everything within the scope of the appended claims and their equivalents.

What is claimed is:

1. A sealed device comprising:
a first glass substrate having a first surface, the first surface comprising an array of cavities, wherein at least one cavity in the array of cavities contains at least one color-converting element;
a second glass substrate; and
at least one seal between the first glass substrate and the second glass substrate, the seal extending around the least one cavity containing the at least one color-converting element.

2. The sealed device of claim 1, wherein the first and second glass substrates, which can be identical or different, comprise a glass chosen from aluminosilicate, alkali-aluminosilicate, borosilicate, alkali-borosilicate, aluminoborosilicate, and alkali-aluminoborosilicate glasses.

3. The sealed device of claim 1, wherein the first and second glass substrates have a thickness, which can be identical or different, ranging from about 0.1 mm to about 2 mm.

4. The sealed device of claim 1, wherein each cavity in the array of cavities has a depth ranging from about 0.02 mm to about 1 mm.

5. The sealed device of claim 1, wherein the at least one color-converting element is chosen from quantum dots, fluorescent dyes, red, green, and blue phosphors, and combinations thereof.

6. The sealed device of claim 1, wherein the second glass substrate comprises a second surface in contact with the first surface of the first glass substrate and the at least one seal is formed between the first and second surfaces.

7. The sealed device of claim 1, wherein the at least one seal comprises a glass-to-glass weld.

8. The sealed device of claim 1, further comprising a sealing layer disposed between the first glass substrate and the second glass substrate and contacting the first surface of the first glass substrate and a second surface of the second glass substrate.

9. The sealed device of claim 8, wherein the sealing layer is chosen from glasses having a glass transition temperature of less than or equal to about 400° C.

10. The sealed device of claim 8, wherein the sealing layer is chosen from glasses having an absorption of greater than about 10% at a predetermined laser wavelength.

11. The sealed device of claim 8, wherein the sealing layer has a thickness ranging from about 0.1 microns to 10 microns.

12. A display device comprising the sealed device of claim 1 and optionally at least one component chosen from a light source, a light guide, a prism film, a linear polarizer, a reflecting polarizer, a thin-film transistor, a liquid crystal layer, a color filter, and combinations thereof.

13. The display device of claim 12, wherein the light source comprises an LED array, and wherein the array of cavities in the sealed device substantially aligns with the LED array.

14. A sealed device comprising:
a first glass substrate having a first surface, the first surface comprising an array of cavities, wherein at least one cavity in the array of cavities contains a color-converting element;
a second glass substrate positioned on the first surface;
an optional sealing layer positioned between the first and second glass substrates; and
a first seal formed between the first glass substrate and the second glass substrate, the first seal extending around the least one cavity containing the at least one color-converting element and the first seal comprising a glass-to-glass seal or comprising a glass-to-sealing layer-to-glass seal.

15. The sealed device of claim 14, wherein the at least one color-converting element is chosen from quantum dots, fluorescent dyes, red, green, and blue phosphors, and combinations thereof.

16. The sealed device of claim 14, further comprising:
a second cavity without a color-converting element, the second cavity adjacent the at least one cavity; and
a second seal formed between the first glass substrate and the second glass substrate, the second seal extending around the second cavity.

17. The sealed device of claim 14, wherein a first cavity in the array of cavities comprises a first color-converting element and a second cavity in the array of cavities comprises a second color-converting element, and wherein the first and second color-converting elements are identical or different.

18. A method for making a sealed device, the method comprising:
placing at least one color-converting element in at least one cavity in an array of cavities on a first surface of a first glass substrate;
bringing a second surface of a second glass substrate into contact with the first surface of the first glass substrate, optionally with a sealing layer between the first and second glass substrates, to form a sealing interface; and
directing a laser beam operating at a predetermined wavelength onto the substrate interface to form a seal between the first substrate and the second substrate, the seal extending around the at least cavity containing the at least one color-converting element.

19. The method of claim 18, wherein the predetermined wavelength is chosen from UV, visible, and near-infrared wavelengths ranging from about 300 nm to about 1600 nm.

20. The method of claim 18, wherein the laser beam operate at a translation speed ranging from about 10 mm/s to about 1000 mm/s.

21. The method of claim 18, wherein the seal has a width ranging from about 20 microns to about 1 mm.

22. The method of claim 18, wherein the first and second glass substrates are brought into contact with an applied compressive force.

23. The method of claim 18, wherein a hermetic seal is formed between the first and second substrates.

24. A sealed device comprising:
a first glass substrate;
a second glass substrate;
a sealing layer positioned between the first and second glass substrates; and
a laser weld seal formed between the first glass substrate and the second glass substrate,
wherein the laser weld seal comprises a hermetic seal reinforced by a non-hermetic seal.

25. The sealed device of claim 24, wherein the non-hermetic seal substantially overlaps with the hermetic seal.

26. The sealed device of claim 24, further comprising at least one cavity.

27. The sealed device of claim 24, wherein the at least one cavity comprises at least one component chosen from laser diodes, light emitting diodes, organic light emitting diodes, quantum dots, and combinations thereof.

28. A method for making a sealed device, the method comprising:
bringing a first surface of a first glass substrate and a second surface of a second glass substrate into contact with a sealing layer to form a sealing interface;
directing a first laser operating at a first predetermined wavelength onto the sealing interface to form a hermetic seal between the first glass substrate and the second glass substrate; and
directing a second laser operating at a second predetermined wavelength onto the sealing interface to form a non-hermetic seal between the first glass substrate and the second glass substrate.

29. The method of claim 28, wherein the hermetic seal and the non-hermetic seal substantially overlap.

30. The method of claim 28, wherein the first laser operates at a translation speed (V) according to formula (a):
V/(D*r)≦1 (a)
wherein D is the spot diameter of the laser beam at the sealing interface and r is the repetition rate or modulation speed of the first laser.

31. The method of claim 28, wherein the second laser operates at a translation speed (V) according to formula (b):
V/(D*r)>1 (b)
wherein D is the spot diameter of the laser beam at the sealing interface and r is the repetition rate or modulation speed of the second laser.

32. The method of claim 28, further comprising placing at least one component in at least one cavity on the first or second surface prior to sealing the first and second glass substrates.

33. The method of claim 32, wherein the at least one component is chosen from laser diodes, light emitting diodes, organic light emitting diodes, quantum dots, and combinations thereof.

34. A method for making a sealed device, the method comprising:
bringing a first surface of a first glass substrate and a second surface of a second glass substrate into contact with a sealing layer to form a sealing interface;
directing a laser operating at a predetermined wavelength onto the sealing interface to form at least one seal line between the first glass substrate and the second glass substrate, the at least one seal line defining at least two sealed regions; and
separating the at least two sealed regions along at least one separation line,
wherein the at least one seal and the at least one separation line do not intersect.

35. The method of claim 34, wherein the at least one seal line comprises a plurality of closed loop seals.

36. The method of claim 34, wherein the at least one seal line comprises a plurality of intersecting seal lines.

37. The method of claim 34, further comprising placing a mask on a second surface of the first glass substrate or a first surface of the second glass substrate, wherein the mask blocks absorption by the sealing interface at the predetermined wavelength.

38. The method of claim 37, wherein the mask is patterned on the second surface of the first glass substrate or the first surface of the second glass substrate to form at least one non-absorbing region, and wherein the at least one separation line is positioned in the at least one non-absorbing region.

39. The method of claim 34, wherein at least one of the sealed regions comprises at least one cavity optionally containing at least one component.

40. The method of claim 39, wherein the at least one component is chosen from laser diodes, light emitting diodes, organic light emitting diodes, quantum dots, and combinations thereof.

41. The method of claim 34, wherein at least one of the sealed regions comprises a plurality of individually sealed cavities.
